(19) United States
(12) Patent Application Publication
(10) Pub. No.: US 2025/0029810 A1
(43) Pub. Date: Jan. 23, 2025

(54) METHODS AND SYSTEMS FOR SELECTIVELY MANAGING IMAGE AND METADATA FROM TRANSMISSION ELECTRON MICROSCOPE (TEM) SESSIONS AT MULTIPLE TEMPORAL OR SPATIAL RESOLUTIONS

(71) Applicant: Protochips, Inc., Morrisville, NC (US)

(72) Inventors: Franklin Stampley Walden, II, Raleigh, NC (US); John Damiano, JR., Holly Springs, NC (US); David P. Nackashi, Raleigh, NC (US); Daniel Stephen Gardiner, Wake Forest, NC (US); Mark Uebel, Morrisville, NC (US); Alan Philip Franks, Durham, NC (US); Joshua Friend, Raleigh, NC (US); Katherine Marusak Stephens, Garner, NC (US)

(21) Appl. No.: 18/778,444

(22) Filed: Jul. 19, 2024

Related U.S. Application Data
(60) Provisional application No. 63/514,983, filed on Jul. 21, 2023.

(51) Int. Cl. H01J 37/244; H04N 23/667

(52) U.S. Cl. CPC H01J 37/244; H04N 23/667; H01J 2237/221

(57) ABSTRACT

Disclosed herein are methods and systems for selectively managing different temporal and/or spatial resolution images and metadata collected during a transmission electron microscope (TEM) session. The system includes a transmission electron microscope and a computer system communicatively coupled to the transmission electron microscope. The computer system includes memory, data storage, and at least one processor configured for continuously receiving, from the transmission electron microscope, data captured at a lower temporal and/or spatial resolution and selectively receiving, from the transmission electron microscope, data captured at a higher temporal and/or spatial resolution.

### CROSS-REFERENCE TO RELATED APPLICATIONS

The application claims priority to U.S. Provisional Patent Application No. 63/514,983 filed on Jul. 21, 2023 by Protochips, Inc. entitled “METHODS AND SYSTEMS FOR SELECTIVELY MANAGING IMAGE AND METADATA FROM TRANSMISSION ELECTRON MICROSCOPE (TEM) SESSIONS AT MULTIPLE TEMPORAL OR SPATIAL RESOLUTIONS,” the entire content of which is incorporated by reference herein.

### TECHNICAL FIELD

The present disclosure relates to the field of electron microscopy, and particularly to methods and systems for selectively managing different temporal and/or spatial resolution TEM images and metadata.

### BACKGROUND

In in situ microscopy, a transmission electron microscope (TEM) or scanning transmission electron microscope (STEM) uses a beam of electrons transmitted through a specimen in a sample holder to form an image. The TEM or STEM is used during experiments or experimental sessions to observe the sample over a period of time. One burden in the field of in situ microscopy, and generally all TEM microscopy, is the total amount of data accumulated both during a session and over the course of time. A single TEM session may span many hours and may generate thousands or millions of images and many GB or TB of data. It is not unusual for a user to collect thousands or more of 16MP images in a single session, which may total many terabytes of data. Additionally, users may accumulate many sessions on a single sample type across many TEMs. Modern cameras can collect coherent images at frame rates exceeding 40frames/second at the maximum resolution, with trends toward an order of magnitude faster within the next five years. Thus, the volume of data generated from experimental sessions is large and unwieldy to analyze. Post-experiment analysis of such a large amount of data can be tedious, time-consuming, and resource intensive.

Some tools can continuously collect lower resolution images and metadata fast enough to make live decisions throughout a TEM session and save data to help put key sequences in context, but it is not often desirable to continuously collect and store high resolution TEM images through the entire session because many of these large images are not valuable to the user.

No tools currently exist for providing workflows that help users visualize, distill, and select whether to keep or discard image sequences while avoiding unwanted bloat in the captured data. Thus, opportunities exist for providing a novel approach for continuously recording data at a lower temporal resolution and/or a lower spatial resolution throughout a TEM session and selectively recording higher temporal resolution and/or spatial resolution images.

### SUMMARY

This summary is provided to introduce in a simplified form concepts that are further described in the following detailed descriptions. This summary is not intended to identify key features or essential features of the claimed subject matter, nor is it to be construed as limiting the scope of the claimed subject matter.

The methods and systems of described herein use experimental metadata, TEM metadata, and camera metadata from current and past experimental sessions taken from one or more different TEMs to provide users to a novel way to record, store, and manage image data and metadata at lower temporal and/or spatial resolutions and at higher temporal and/or spatial resolutions throughout a TEM session in an efficient manner.

According to one embodiment, the subject matter disclosed herein includes a system for selectively managing different temporal and/or spatial resolution TEM images and metadata. collected during a transmission electron microscope (TEM) session. The system includes a transmission electron microscope and a computer system communicatively coupled to the transmission electron microscope. The computer system includes memory, data storage, and at least one processor configured for continuously receiving, from the transmission electron microscope, data captured at a lower temporal and/or spatial resolution and selectively receiving, from the transmission electron microscope or attached imaging system, data captured at a higher temporal and/or spatial resolution. For example, in many TEM architectures a computer controls the column, and another computer controls operations of the imaging system (camera, STEM detectors, electron energy loss spectroscopy (EELS), or energy dispersive X-ray spectroscopy (EDS)). As used herein, a TEM instrument may be understood broadly to include these various computers for controlling components or systems of an attached imaging system.

According to another embodiment, the subject matter disclosed herein for selectively managing different temporal and/or spatial resolution TEM images includes a non-transitory computer-readable storage medium storing instructions to be implemented on at least one computing device. The instructions, when executed by at least one processor of the at least one computing device, cause the at least one computing device to continuously receive, from the transmission electron microscope, data captured at a lower temporal and/or spatial resolution and selectively receive, from the transmission electron microscope, data captured at a higher temporal and/or spatial resolution.

According to another embodiment, the subject matter disclosed herein includes a method for selectively managing different temporal and/or spatial resolution images and metadata collected during a transmission electron microscope (TEM) session. The method is performed by a transmission electron microscope and a computer system communicatively coupled to the transmission electron microscope and associated camera systems and includes continuously receiving, from the transmission electron microscope, data captured at a lower temporal and/or spatial resolution and selectively receiving, from the transmission electron microscope, data captured at a higher temporal and/or spatial resolution.

### BRIEF DESCRIPTION OF THE FIGURES

FIG. 1 depicts one embodiment of the system for selectively managing different temporal and/or spatial resolution TEM images and metadata described herein.

FIG. 2 depicts exemplary steps of a method for selectively managing different temporal and/or spatial resolution TEM images and metadata.

FIG. 3 depicts a data architecture of an exemplary embodiment for collecting and selecting different temporal and/or spatial resolution TEM images and metadata described herein.

FIG. 4 depicts an exemplary hardware configuration and workflow for managing different temporal and/or spatial resolution TEM images and metadata according to an embodiment described herein.

FIG. 5 depicts a UI presented by the data management system described herein.

FIG. 6 depicts a detailed view of the timeline UI of the HFR data management system described herein.

FIG. 7 depicts a view of the UI of the system described herein showing available HFR data and consolidated HFR data.

FIG. 8 depicts a detailed view the UI in FIG. 7 showing consolidated HFR data.

FIG. 9 depicts a UI presented by the data management system described herein.

FIG. 10A depicts a first part of a sequence for managing TEM images and metadata according to an embodiment described herein.

FIG. 10B depicts a second part of the sequence in FIG. 10A for managing TEM images and metadata according to an embodiment described herein.

FIG. 11 depicts an alternative data management sequence for managing TEM images and metadata to the sequence shown in FIGS. 10A and 10B.

FIG. 12 depicts an alternative data management sequence for managing TEM images and metadata to the sequence shown in FIGS. 10A and 10B.

FIG. 13 depicts UI elements for an HTR image transfer service according to one embodiment of the data management system described herein.

FIG. 14 depicts UI elements for an HTR image transfer service according to one embodiment of the data management system described herein.

### DETAILED DESCRIPTION

Below, the technical solutions in the examples of the present disclosure are depicted clearly and comprehensively with reference to the figures according to the examples of the present disclosure. Obviously, the examples depicted here are merely some examples, but not all examples of the present disclosure. In general, the components in the examples of the present disclosure depicted and shown in the figures herein can be arranged and designed according to different configurations. Thus, the detailed description of the examples of the present disclosure provided in the figures below are not intended to limit the scope of the present disclosure as claimed, but merely represent selected examples of the present disclosure. Based on the examples of the present disclosure, all other examples that could be obtained by a person skilled in the art without using inventive efforts will fall within the scope of protection of the present disclosure. The present disclosure will now we described with reference to the Figures shown below.

The systems and methods described herein improves the functioning of a computer by selectively recording at a higher resolution data, while continuously recorded lower resolution data, generated during an experimental session using a TEM and by generating an interactive visual representation of what happened during an experimental session using a TEM. The system and the generated interactive visual representation allow a user to manage a data workflow associated with operation of the TEM in a novel way, by allowing the user to keep the highest resolution data without being overwhelmed by an excessive amount of unwanted data. The systems and methods described herein, therefore, improve the functioning of a computer by allowing for efficient management of image data and metadata.

### Terminology

As used herein, the term “session” refers to the duration for a single microscope instance without exchanging samples or holders.

As used herein, the term “tag” refers to a name or identifier that can be attached to any number of images.

As used herein, the term “collection” refers to a set of images and their associated metadata persisted in a single database.

As used herein, the term “project” refers to a collection of sessions, even from different TEMs, into which a user can organize experimental data.

As used herein, the term “publish” refers to saving images or metadata out of the database into industry-standard formats, such as, for example, PNG files, CSV files, MP4 files, or the like.

As used herein, the term “workspace” refers to a configuration that includes specific filters, collections, and other settings. An individual workspace refers to an individual desk with individual data storage (e.g., a desktop or laptop computer). A small group workspace refers to small groups or teams that manage their data locally in a shared space.

### Overview

The methods and systems described herein may be embodied in the Protochips AXON Studio, which is a metadata and image management system for reviewing TEM sessions generated through the Protochips AXON Synchronicity software package and may be implemented as part of a software environment that is connected to a TEM. The software environment may be implemented on an individual workspace, a small group workspace, or a networked workspace configured as part of a cloud-based system. The workspaces may be any type of computing device, including, for example, a desktop computer, a laptop computer, a mobile device such as a tablet or a smartphone, and/or a client in a client-server system.

The system described herein may be configured to interface with an electron microscope, such as a transmission electron microscope (TEM) or a scanning transmission electron microscope (STEM), among others. For example, image data may be received from a camera or a detector system on the microscope, where the cameras or detectors execute imaging software on a computing device that is communicatively coupled to the system described herein via a communications network. The use of heating, liquid cells, and/or gas in situ systems with the TEM or STEM allows the collection of images aligned with experimental metadata. The metadata includes, for example, temperature, gas, pressure, mass spectrometer, etc. Each image has associated with it a set of metadata that describes aspects of the image or the experiment at the time the image was captured. The metadata includes the results of analysis run in AXON Studio. Math and models may be applied to a “working set” or an entire “collection” using existing metadata values. Additionally, image analysis, image filters, or selected area pixel intensity statistics that may be applied to a single image may also be applied to a “working set” or an entire “collection.” These calculated metadata values can be saved to the database and used like the metadata parameters saved live with the image. They may be filtered on, plotted, published, overlaid on the image, making it easy to see how these derived metadata values change over time through the image sequence.

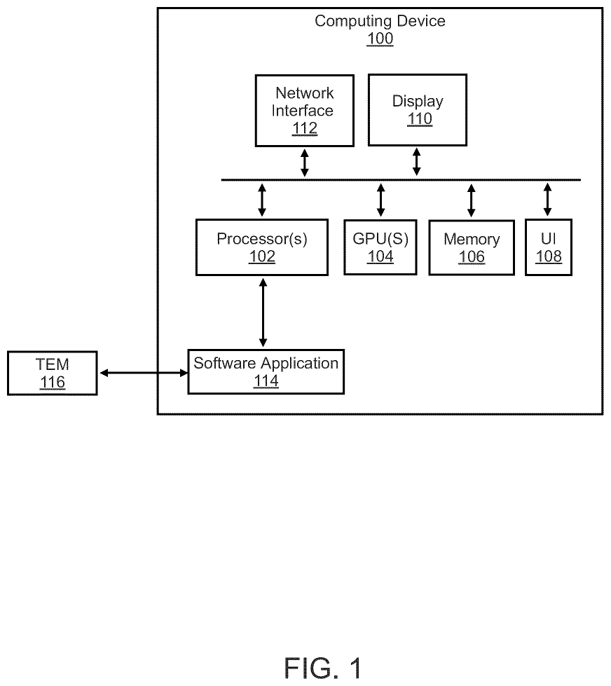

FIG. 1 depicts one embodiment of the system of metadata management for a transmission electron microscope described herein. Referring to FIG. 1, the computing device 100 may include at least one processor 102, at least one graphical processing unit (“GPU”) 104, a memory 106, a user interface (“UI”) 108, a display 110, and a network interface 112. The memory 106 may be partially integrated with the processor(s) 102 and/or the GPU(s) 104. The UI 108 may include a keyboard and a mouse. The display 110 and the UI 108 may provide any of the GUIs in the embodiments of this disclosure. AXON software 114 runs on the computing device 100. As noted above, the computing device 100 may be a single computing device (e.g., a laptop, a desktop computer, or a server), multiple networked computing devices, and/or a cloud server. AXON software may be communicatively coupled to transmission electron microscope (TEM) and/or associated cameras, detectors and imaging systems 116. The computing device 100 receives data from TEM 116 during one or more experimental sessions. The received data includes image data and metadata from TEM 116. The image data may be captured continuously at a lower spatial or temporal resolution and selectively capture or recorded at a higher spatial or temporal resolution. It may be appreciated, for example, that resolution can include either spatial resolution or temporal resolution and that the system disclosed herein can, therefore, connect at a lower framerate (temporal resolution) or with smaller image pixels (spatial resolution) versus the image data that is recorded/captured.

### Method

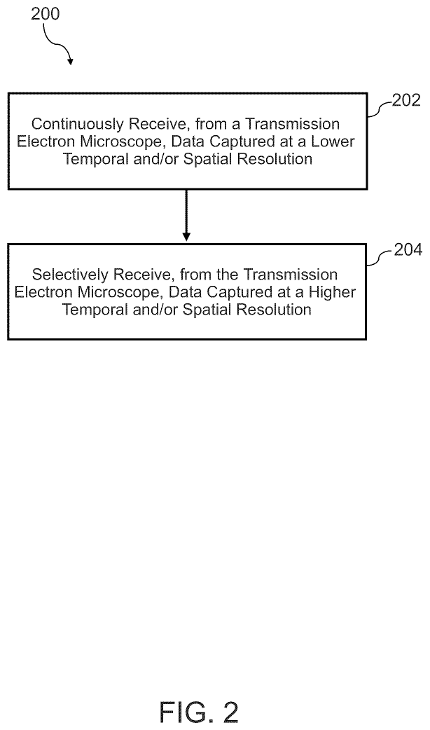

FIG. 2 depicts exemplary steps of a method for selectively managing different temporal and/or spatial resolution TEM images and metadata. The method for selectively managing different temporal and/or spatial resolution images and metadata collected during a transmission electron microscope (TEM) session may be performed by a system comprising a transmission electron microscope and a computer system communicatively coupled to the transmission electron microscope that includes memory, data storage, and at least one processor configured for performing steps of the method.

Consider, for example, an in situ user that wants to quickly manually identify a specific section of their last experiment and record high resolution or high frate rate data of that section. The user may not know exactly what section of their experiment they are looking for, but they know they can quickly ignore the first part of the session while they were looking for a good site and warming the sample to prevent contamination by scrubbing through the timeline, which is fast and complete because it includes lower-resolution data. When the user finds the right time, they can trigger the capture of higher-resolution data. Since the user is only interested in capturing a few higher-resolution segments, which the user triggered by manually adjusting the start and stop points based on what the user sees happening to the sample, the amount of data created is significantly less than would be required with continuous (i.e., non-selective) recording of both lower resolution and higher resolution data. This lessens the burden on various computing, network, and data storage resources, without giving up on capturing any desired data, that the user can efficiently manage, communicate, store, and distribute the captured data among devices which would not otherwise be possible. It may be appreciated that, as used herein, the terms “capture” and “record” may be used interchangeably to describe the action of saving data to disk. Some vendors may use “Capture” and may other vendors use “Record”.

Thus, the method described herein provides a workflow that helps users visualize, distill, and select whether to keep or discard image and/or metadata sequences. The workflow may result in a collection of images and metadata spanning most, if not an entire, TEM session. The collection of images and metadata captures everything about the sample at a lower temporal and/or spatial resolution, but also includes higher temporal and/or spatial resolution images and metadata at the right sequences.

A benefit of the disclosed method is that it gives users the continuous data while also putting the large data sequences in context telling the full story of what happened to the sample. This context includes before/after images as well as information related to the image(s), microscope, position, dose, in-situ stimuli, etc.

Another benefit of the disclosed method is that it helps users avoid bloat in the captured data. This more manageable data size is easier, cheaper, and faster to share, store, and analyze.

Step 200 of the method includes continuously receiving, from the transmission electron microscope or associated camera or detector imaging systems, data captured at a lower temporal and/or spatial resolution. For example, in addition to different types of image data that may be generated, when a TEM or STEM experiment is performed, there are a number of different types of metadata that may be tracked on a per-image basis and may be used to track session data.

The metadata may include the name, time, duration, date, location, and type of experiment of the experimental session. The metadata may further include the type of electron microscope used for the experimental session. The metadata may further include the type of environment used for the experimental session. The environment may include in-situ stimuli, in-situ environment, sample support, sample dilution, and the like. The metadata may further include a type of camera or STEM detector used for the experimental session, as well as the camera or STEM detector settings, such as image binning, resolution, brightness, contrast, and the like. The metadata may further include the time during the experimental session when a particular image was captured.

The metadata may further include measurements taken during the experimental session. The measurements may be taken at the sample or sample environment, or they may be taken either upstream or downstream from the sample or sample environment. For example, a residual gas analyzer may be used downstream of the sample to determine any by-product of a reaction. The metadata may include a mass spectrometry value of the sample, which may be taken at the sample or either upstream or downstream from the sample.

The metadata may further include a type of the sample, as well as notes relating to the sample preparation, such as sample dilution, FIB parameters, blotting parameters, sample preparation strategy, plasma cleaning parameters, surface preparation strategy, and the like. The metadata may further include flow-rate, temperature, gas composition, and pressure of the sample. The metadata may further include a focus score, which is a value that may be calculated for each image that indicates the quality of the image (e.g., by using a variance, or by using a gradient). The metadata may further include additional information, such as tags, live notes, and/or image descriptions that may be added to one or more images in a sequence or collection. The metadata value may further include particle size, particle distribution, and crystallinity percentage for one or more images in a sequence or collection.

In addition to live metadata, session metadata may be applied to an entire session rather than to a specific frame. There are varying types and amounts of metadata that may be associated with a session, so session metadata may be technique driven, which allows for flexible metadata to be added depending on the specifics of the session.

The system described herein may also provide for exporting the image data as image files in one or more various industry-standard formats, so that the image data can be exported to be presented or otherwise used outside of the system.

The image analysis metadata described herein may be more valuable on a drift-corrected sequence of images because images can be normalized to show how the sample has changed over time. For example, during a TEM session, live calculations may be run on all live drift-corrected frames to generate normalized data sets. The live calculations may include focus quality, match correlation, percent crystallinity, image contrast, or the like. Drift corrected images also enable normalized focus scores against best possible or best recorded on that sample. A match correlation can be determined to isolate good frames from torn frames or bad frames. Match correlation is also useful in determining when the sample is reacting vs. when it is stable.

Additionally, other image analysis calculations may include quantifying contrast, image pixel variance, and image intensity. The image processing calculations may be performed across the entire image or a subset of the image. The image processing calculations may be performed live as the images are captured, or they may be performed after the fact. Metadata properties may include, for example, measurements, state and calculations from the TEM, camera, detectors and connected in-situ or auxiliary systems.

In the various embodiments described above, the metadata may include any one or more of the following: a value identifying the experimental session, a value indicating a type of electron microscope used for the experimental session, a value indicating a type of environment used for the experimental session, a value indicating a type of camera or STEM detector used for the experimental session, values indicating camera or STEM detector settings used for the experimental session, a measurement of the sample taken during the experimental session, a flow-rate of the sample during the experimental session, a date of the experimental session, a value indicating a type of experiment of the experimental session, a value indicating a type of sample of the experimental session, values indicating sample preparation notes of the sample of the experimental session, a focus score value that indicates quality of the associated image, a temperature value of the sample when the associated image was captured, a gas composition in the sample when the associated image was captured, a pressure value of the sample when the associated image was captured, a mass spectrometry value of the sample when the associated image was captured, a time value indicating when during the experiment the associated image was captured, a tag for the associated image, a live note for the associated image, an image description for the associated image data, a value indicating particle size for the associated image, a value indicating particle distribution for the associated image, a value indicating crystallinity percentage for the associated image. The measurement of the sample taken during the experimental session is an upstream measurement or a downstream measurement. The mass spectrometry value of the sample is an upstream value or a downstream value.

Step 202 of the method includes selectively receiving, from the transmission electron microscope, data captured at a higher temporal and/or spatial resolution. The data includes a plurality of images and associated metadata. Selectively receiving the higher resolution data may include communicating with the transmission electron microscope for instructing the transmission electron microscope to begin or end recording at a higher temporal resolution (e.g., higher frame rate/greater number of images captured per time interval), at a higher spatial resolution (e.g., higher pixel density images), or both.

To enable the TEM camera to record at full spatial and temporal resolution locally while simultaneously recording a lower resolution data stream, the TEM camera may generate a live image and metadata stream available for analysis. The temporal and spatial resolution of this live image and metadata stream may target a data rate that a data storage device is capable of recording.

Some TEM cameras also have a “lookback” option or feature that allows the user to command the camera to record data in a buffer spanning a few seconds before the command.

In one embodiment, a lower temporal data stream can be created by summing or averaging multiple high-speed images into one or more blocks. This may include summing the pixel information in a number of continuous images (e.g., 5) before normalizing. One advantage of this method for creating a lower temporal data stream is that it slows the temporal resolution in the continuous data stream while allowing the camera to run at the full speed with relatively low dose. The user can then see the slower image rate with summed data over a period of time. Because there is more information and less noise in these summed images, they may be well-suited for use by both automated systems and users. For example, a user can decide whether they want to record higher frame rate data based on a live analysis of the slower, summed images. Another advantage is that these slower, summed images may be easier to scrub through when deciding whether the higher frame rate data is valuable. In this way, the lower resolution image data stream can be created by digitally binning the live images and users can pick a different pixel resolution than the camera's native behavior. The terms “digitally binning”, “pixel binning”, “image binning”, or simply “binning” refers to a process of combining adjacent pixels throughout an image by summing or averaging their values. For example, in 2×2 binning, a cluster or an array of 4 pixels may become a single larger pixel, thereby reducing the number of pixels to ¼ and halving the image resolution in each dimension. The result of binning can be the sum, average, median, minimum, or maximum value of the cluster. While the binned image may have a lower resolution, the relative noise level in each pixel may be reduced.

The lower resolution image data stream can also be created by throttling the available image stream. Throttling the image data stream can be performed by expressly limiting the polling frequency of the image data stream. Alternatively, the image data stream can be limited by the network bandwidth between computers sending and receiving the image data stream. For example, a 5 GBPS stream may be limited to 1 GBPS if the sending device has a data storage system only capable of reading 1 GBPS or a network interface only capable of sending 1 GBPS. Similarly, a 5GBPS stream may be limited to 1 GBPS if the receiving device has a data storage system only capable of writing 1 GBPS or network interface only capable of receiving 1 GBPS.

“Direct Detection” and other modern TEM CMOS or scintillator cameras can generate and/or save high spatial resolution images at a lower frame rate, such as 4096×4096 (i.e., 16.78 megapixels) at 40 frames per second (FPS). They can also generate and/or save high temporal resolution/high frame rate images at a lower resolution, such as 200 FPS at 1080×1080. This may produce data rates of 1-5 gigabytes per second (GBPS) of recorded data. Other camera systems, which can record both high resolution images and at a high frame rate, can produce data rates in excess of 5 GBPS of recorded data.

In one embodiment, selectively receiving the higher resolution data may be performed in response to a trigger. This allows for only recording higher temporal resolution and/or spatial resolution images at the right time, which may be determined by the user based on their analysis of the lower resolution data or other experience. It may also be based on satisfying predefined criteria which is implemented in software and/or hardware to automatically determine the “right time” to record higher temporal resolution and/or spatial resolution images.

As mentioned, in one embodiment, the selective recording of the higher temporal resolution and/or spatial resolution images is manually triggered. For example, a user interacting with a camera or imaging software may generate a signal that is detected at a trigger for initiating high resolution data capture. This may include a physical button, such as a button integrated with the camera programmed to generate the trigger, or a virtual button, such as an interactive element of a software-based user interface.

As mentioned, in another embodiment, the selective recording of the higher temporal resolution and/or spatial resolution images is triggered automatically. For example, automatically triggering the recording of the higher temporal resolution and/or spatial resolution images may be based on the data captured at a lower temporal resolution and/or lower spatial resolution.

In addition to the steps shown in FIG. 2, the method may include generating a visual representation of the image data and the metadata in an interactive timeline format. For example, a timeline may display a chronological arrangement of events in the order of their occurrence. The timeline may include one or more “tracks” or “layers”, where each track may be displayed to differentiate between the data types (e.g., a different color and/or on a different row of the timeline). Each track may represent different data. For example, high temporal resolution (HTR) or high frequency resolution (HFR) events may be displayed on a first track in pink, drift-corrected events may be displayed on a second track in blue, and Raw events may be displayed on a third track in orange. This way, the user can see which events are available at a point in time on the timeline. It is appreciated, that the particular colors, shapes, or other visual indicators may vary and are not limited to the example embodiments described above.

The timeline allows the user to interact with the TEM session by scrubbing the images and plot data. Timeline “scrubbing” is a method for interacting with the timeline interface where the user clicks and drags a cursor forward or backward to quickly preview a period of time without requiring the user to linearly play the image sequence at a fixed speed or full size.

In some embodiments, the user interface also includes a data layer that is painted on the interactive timeline. The data layer may show whether higher temporal and/or spatial resolution data is available.

It is appreciated that information captured at the lower temporal resolution and/or lower spatial resolution may be referred to as a lower resolution “data stream”. Similarly, information captured at the higher temporal resolution and/or higher spatial resolution may be referred to as a higher resolution data stream.

The method may also include synchronizing the lower resolution data stream with the higher resolution data stream. Synchronizing the data streams may be performed using a software application or service. The software application or service may be executed on a single computer or may be executed on one or more different computers. Likewise, the data streams may be stored locally using data storage associated with a single computer (e.g., an NVME drive) or may be distributed across one or more data storage devices, storage servers, or databases.

In one embodiment, the data streams are synchronized based on an indication in a first data storage location that higher resolution data is available in a second data storage location. For example, a file watcher or profiler may be configured to look for recorded images on a disk. When images appear on the disk (e.g., in a watched folder), the file watcher may automatically begin the synchronization process. Synchronizing the data streams may include, for example, comparing the lower resolution data stream with the higher resolution data stream as part of an image analysis.

According to some embodiments, the method additionally includes performing “live” drift correction during the TEM session in real time or near real time. This may include physical and/or digital drift correction, where the data produced by the drift correction includes a set of drift-corrected images.

In one embodiment, drift correction of higher resolution images and metadata may be based on the lower resolution images and metadata. The higher resolution drift corrected images and metadata may be saved in addition to, or in place of, the lower resolution images and metadata.

In another embodiment, the method also includes applying data management practices to the image data streams. For example, the applied data management practice may include saving every Nth image, digitally summing or averaging pixels in a blocked or rolling average, and/or binning images from one pixel resolution to a different pixel resolution. These actions can be applied before the lower resolution image stream is displayed.

The ability to digitally sum or blocked average the continuous image data enables live or post analysis on less noisy images. This can be advantageous because it allows users to easily scrub image data streams, or help users with automation, for identifying valuable high resolution image stream(s). For example, this may be important when the dose is low, and the frame rate is high because any 1 frame has little counts. If reviewing pre-record, the user can then drift correct continuous image data more reliably or decide when to save the original high speed, low dose images. Alternatively, if reviewing post-record, the user (or an automated system) can review the less noisy images to decide which high speed, low dose images to transfer or merge.

### System Architecture

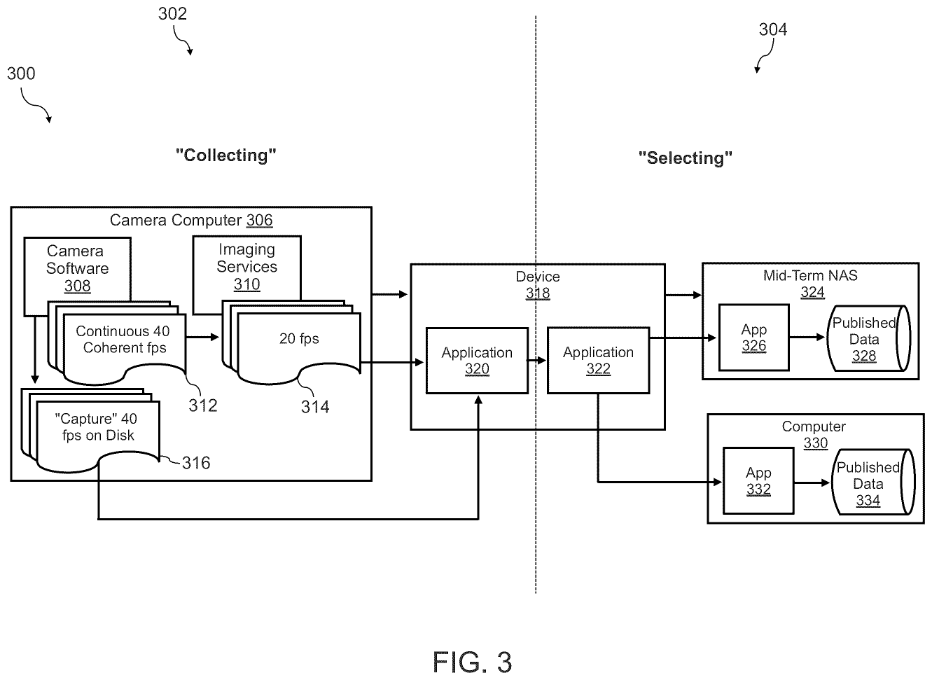

FIG. 3 depicts a data architecture of an exemplary embodiment for collecting and selecting different temporal and/or spatial resolution TEM images and metadata described herein. Referring to FIG. 3, system 300 may be divided into a collecting portion 302 and a selecting portion 304.

The collecting portion 302 of the system 300 may include a camera computer 306 that includes camera software 308 and imaging services 310 for collecting a continuous stream of data 312 (e.g., 40 fps), which may be converted to another stream of data 314 having a different frame rate (e.g., 20 fps), and store the 40 fps data 312 as captured data 316. The captured data may be provided by the camera computer 306 to a computing device 318 (e.g., AXON Core device). The computing device 318 may execute one or more software programs, such as application 320 (e.g., AXON Synchronicity 320) and application 322 (e.g., AXON Studio 322). The computing device 318 may include processors, memory, local data storage, and networking interfaces. For example, computing device 318 may receive the collected data using multiple separate 10 Gbps network interfaces and buffer the data using a 1-2 TB SSD.

The selecting portion 304 of the system 300 may include a mid-term staging NAS 324 and a home/office computer 330. The computing device 318 may communicate data to a NAS 324 and a computer 330 as part of an automated transfer process. The NAS 324 may include a plurality of data storage devices configured in a RAID array or other logical grouping (e.g., 100 TB SATA array) for storing published data 328 and executing a local instance of application 326 (e.g., AXON Studio 326). Similarly, home/office computer 330 may include local data storage devices for storing published data 334 and executing a local instance of application 332 (e.g., AXON Studio 332).

In some TEM systems, “HFR” images may be triggered by “Capture” or “Record” using imager software or through AXON by analysis/trigger or user. Images saved by the camera software may be transferred to active session buffer on AXON PC. Images may then be synchronized into the timeline with intelligent metadata interpolation while users can still manage data through Studio tools and filters.

In many TEM systems, however, the camera computer may be integrated with the TEM and configured to automatically save recorded high-resolution images to the camera computer only when the customer decides to do so. As described herein, a computing device (e.g., AXON Core) may be networked (communicatively coupled) to the computer that is already on the TEM via one or more network connections. In one embodiment, low-resolution images may be collected at a first (slower) rate, potentially binned, and continuously transferred to the computing device (AXON Core computer) to record throughout the entire session (even when the high-resolution data isn't necessarily being recorded). Thus, it may be appreciated that in this scenario, data may be stored in two locations. First, a continuous stream of low-resolution data may be located on the AXON Core that is capturing the entire session. Additionally, it may be appreciated that these images may not be the same pixel size but may be at a slower rate. The slower rate can be created through a number of methods described herein including, but not limited to blocked summing/averaging one or more images so that they are each easier to analyze with less noise. This may be especially valuable when the second stream of images are higher speed with less dose per image.

Second, bursts of high-resolution images may be located on the camera PC. The high-resolution data on the computing device (AXON Core) may be consolidated through a primary network connection (one through secondary network connection if the first is in use or unavailable). Users can then synchronize all the high resolution data or, alternatively, users can be selective and only consolidate a portion of the high resolution data based on an analysis of the lower resolution images.

Additionally, the system 300 provides for standard polling on “Raw” and “Drift Corrected” images (6.5fps on 2k images) and bursts of HTR records at full spatial and temporal resolution (40 fps on 4k images—or camera limited). HTR images may be integrated into the AXON Timeline with intelligent metadata interpolation. HTR images may be noted on AXON Studio timeline in a new layer. Images may be drift corrected against raw polling templates.

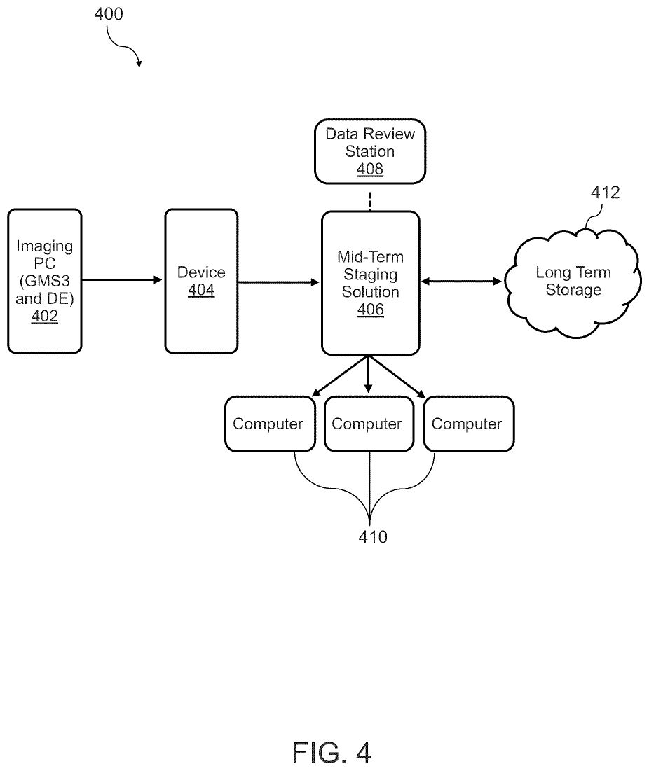

FIG. 4 depicts an exemplary hardware configuration for managing different temporal and/or spatial resolution TEM images and metadata according to an embodiment described herein. Referring to FIG. 4, imaging computer 402 may capture, for example, 10 minutes of data in a few bursts at a frame rate of 40-200 fps, which may produce between 1.13 and 5.64 GBps of data. Imaging PC 402 may also capture 8 hours of continuous image data at a lower resolution and/or frame rate. For example, 480 minutes (e.g., 806.4-1,612.8 GB) of data at 2-16 FPS (e.g., 0.028-0.056 GBps. When combined with the 10 minutes of HFR data, this may result in between 120,000 and 580,000 images and between 2,300 and 5,000 GB of data. The imaging PC 402 may communicate data to device 404 (e.g., Axon core device 404) via a 10 GBps link.

AXON core device 404 may process also communicate with a mid-term staging solution 406, such as a NAS. The mid-term staging solution 406 may be connected to a plurality of devices such as a data review station 408 executing Studio software, various individual workstation computers 410, each executing an instance of the Studio software, and a long term storage facility 412. The long term storage facility 412 may be a cloud-based or other data storage service that may be optimized for receiving and storing large amounts of data at a low cost rather than for constantly reading and transmitting the data.

### User Interface and Workflow(s)

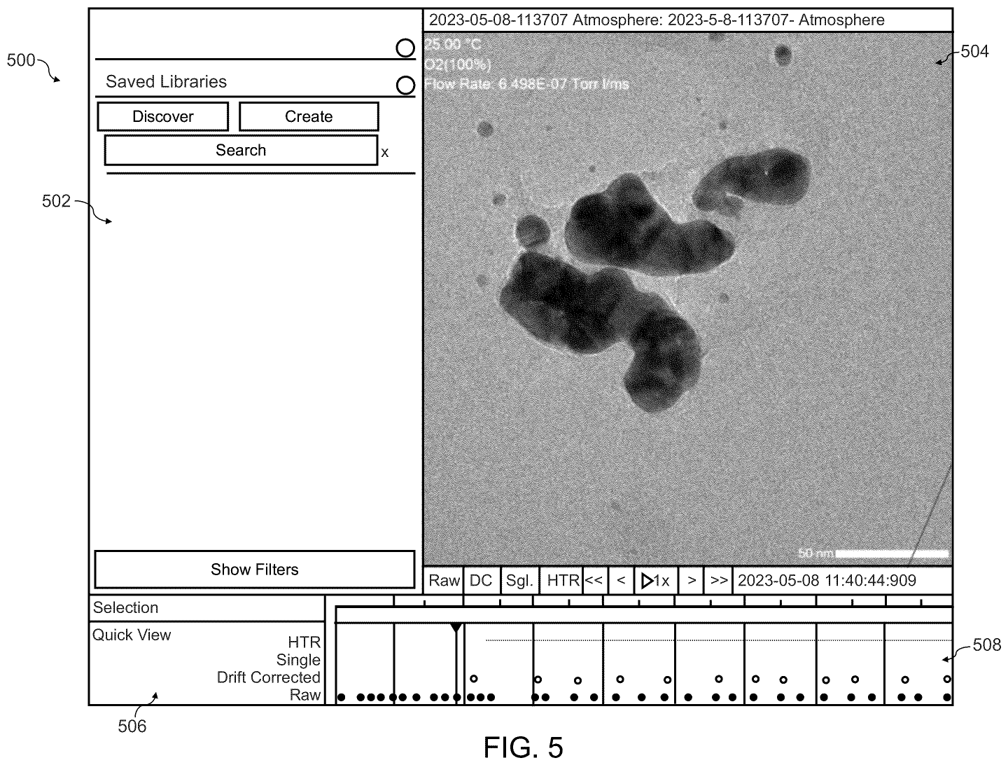

FIG. 5 depicts a UI for high temporal resolution (HTR) data, which may include or also be referred to as high frame rate (HFR) data, that may be presented by the data management system described herein. The UI shown in FIG. 5 may be divided into various sections, panes, layers, portions, or other layers for displaying different types of information and providing different types of user interaction. For example, the UI 500 may include a saved libraries section 502, a main view section 504 a quick view 506, and a timeline 508.

According to embodiments of the present disclosure, metadata properties may be used to generate collections of images and their associated metadata.

A user may organize a group of images and the associated metadata into collections. A collection may span multiple sessions (i.e., time spent on the microscope from sample insertion to removing the sample at the end of the imaging session or experiment), or it may be a subset of a single session.

A single image file may be included in many different collections without being duplicated in memory. There is one underlying image file, but it can be included in the various collections using metadata tags that indicate inclusion in the collections. This avoids duplicating large files across multiple locations on a hard disk. In embodiments described herein, the original session for an image can be determined from the image, but the image may be associated with many different collections without duplicating the image data.

The collections may be nested in a hierarchical fashion (e.g., as a folder structure), but each image references back to the original session in which it was captured. Collections may include multiple sessions as a binder to organize like image sequences.

As shown in FIG. 5, the Saved Libraries 502 may hold session data (e.g., “Session 1Subdirectory,” “Session 2 Subdirectory,” and “Session 3 Subdirectory”). Each archive is stored at a filepath or directory. Each archive may be located locally on a computer or remotely in a networked configuration, such as in a cloud-based architecture. Each archive (e.g., database folder) comprises a single database (xx.axon file) and one or many session folders. Each session folder comprises subdirectories for all image types (e.g., raw images, drift corrected images, single acquisition images, etc.), as well as session metadata that applies to the entire session (e.g., “Session Metadata”). Images are saved in the session folder using unique names for each image. The stored images include all live metadata properties saved to the PNG file as a backup, which may be used to recreate the database file if necessary.

Each image is stored in a directory (either locally or remotely), and the database references the stored images using a filepath. The database is used as the primary record of all metadata properties and may be queried to display data to the user. Although it is possible to store all images in the database, it is preferable to store the images at a filepath in a directory, as described herein, because it provides for quick querying of the database.

According to embodiments of the present disclosure, the system may provide a user with an interactive graphical representation that shows a timeline of the complete history of what happened through an experiment.

In one embodiment, the timeline may be interactive, enabling users to select images or to provide additional functionality, such as hovering over image markers to see a preview of the image, clicking on image markers to navigate the image view to that image in the sequence, selecting images to save as a collection, selecting images to publish an image stack, providing a metadata report or video, selecting images to apply a tag, editing tag duration, text, or description, selecting images to hide or remove them from the view, selecting images to delete from a Session, Collection, or Archive, selecting images to average together into a single high-resolution image to be highlighted on the timeline, or the like.

In one embodiment, to reduce the total library disk size, but preserve the context needed to explain key sequences, a user may want to reduce the resolution, block average or remove every nth image from a sequence of less importance leading up to or following the key sequence. Interacting with the timeline allows users to segregate and treat sequences differently.

The timeline 508 provides a chronological lab notebook generated from live measurements and user-entered notes that are indexed to the captured images.

The timeline may include a quick-view layer that allows the user to easily visualize what image types are available. For example, a user may want to see when they were running a drift correction, or when they captured a single high-resolution capture, or when they have high temporal resolution (e.g., faster frame rate data). A user may scrub against the timeline to see how the TEM or STEM image changed. As the timeline 508 is scrubbed, the user may reference notes and watch for metadata trends. The timeline provides the user a context for the images.

It is appreciated that the lower temporal and/or spatial resolution images and metadata arranged on a Timeline, like in AXON Studio, where users can scrub over the images and plot data to interact with that session including a data layer painted on that Timeline showing when and where higher temporal and/or spatial resolution data is available is only possible once the two data streams are synchronized, even when the data may be on two different computers or storage servers. The two data streams can be synchronized using a software application or service, potentially running on two computers noting in a database or file when higher resolution data is available in another location. Alternatively, this synchronization can be done with a file watcher or profiler looking for recorded images on disk. The synchronization can be improved by image analysis, comparing the information between the lower resolution data stream and the higher resolution images available.

With a data layer painted on the Timeline alongside the lower resolution data stream, a user could scrub and analyze the lower temporal and/or spatial resolution images and/or associated metadata and then decide which sequences of higher spatial and/or temporal resolution data they would like to preserve based on analysis of the lower resolution images and metadata. If the data streams are on two separate computers or storage systems, users can be selective in what data they consolidate on either computer. Users could replace the lower resolution data in overlapping sequences or keep the two data streams consolidated in a single library. Users can then more easily decide to discard high data sequences that do not add value (where nothing changes in the sample, the image quality isn't satisfactory, or the sample didn't “behave”), potentially keeping the lower resolution images and data available.

The timeline 508 may further include a tags layer. Frames or time sequences may be tagged with, for example, experimental notes or observations. The tags may be searchable, selectable, and editable.

The timeline 508 may further include metadata plots. The metadata may be plotted against time, such that the metadata can be visualized over time. The metadata plots may be used for navigating to critical moments during the session. Peaks, valleys, and transitions in metadata plots are often sequences of interest. Users can double-click on the timeline to jump to that image.

The timeline 508 provides an interactive graphical or visual representation of correlations and/or connections between images in the underlying data of the metadata management system stored in the data archives using metadata. The Timeline Panel provides the user with access to the image metadata of the underlying images. Then access to the image metadata allows the user to apply filters to select a subset of images from the image database. The Timeline Panel further provides an interactive visual or graphical representation that allows the user to interact with the collection of images across time. For example, the user may hover the cursor over any point on the timeline to get a preview of the particular image for that point in time in the experimental session. Additionally, the image for that point in time where the cursor is located on the timeline is displayed in the Image View Panel. Moving the cursor along the timeline allows the user to see how the experimental data evolves over time during the experiment.

As shown in timeline 508, various indicators (e.g., colored dots or hash marks) may be shown on the timeline associated with an AXON Synchronicity live image poll. Higher temporal or higher spatial images Synchronized by AXON Image data can be consolidated into a single Library, showing the separate data streams. Workflows help users distill, promote and strategically capture this higher resolution data.

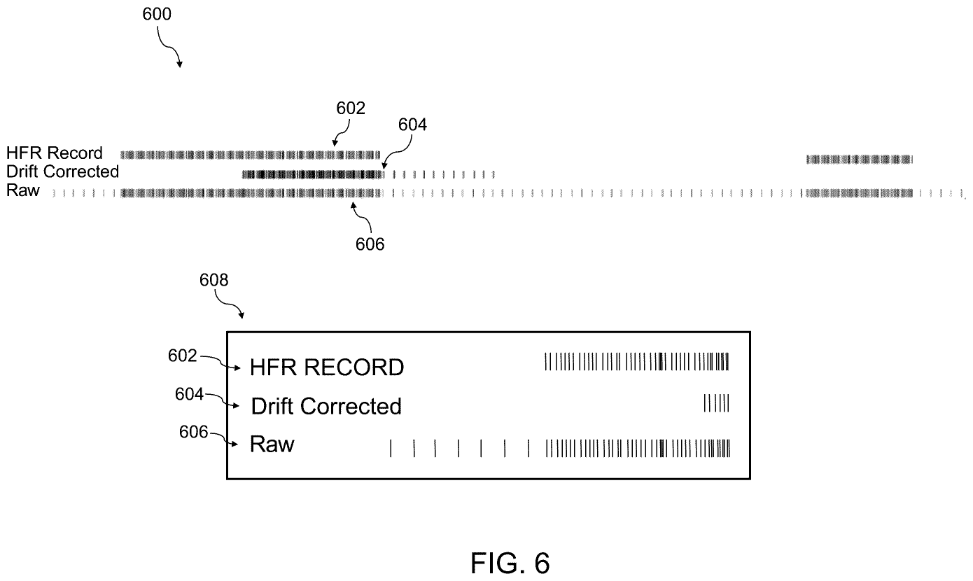

FIG. 6 depicts a detailed view of the timeline UI of the HFR data management system described herein. Referring to FIG. 6, a timeline view 600 of three types of data are shown: HFR Record data 602, Drift Corrected data 604, and Raw data 606. FIG. 6 also shows an enlarged view 608 showing how the HFR data stream 602 can be promoted into the Drift Corrected data stream 604 and the slower Raw data stream 606, as indicted by the high-density points in those sequences shown as overlapping with HFR data.

According to one aspect, the AXON data management systema and strategy described herein is compatible with various imaging systems. This allows users to stay connected throughout an experiment, recording the at full resolution, but enables users to record key sequences as fast as the imaging system allows, at full resolution. Camera computers will be connected to the AXON Core computer through 10 GBPS NICs, effective immediately. Open 10 GBPS NIC (or fiber) for moving temporary buffer to dedicated mid-term or personal storage systems.

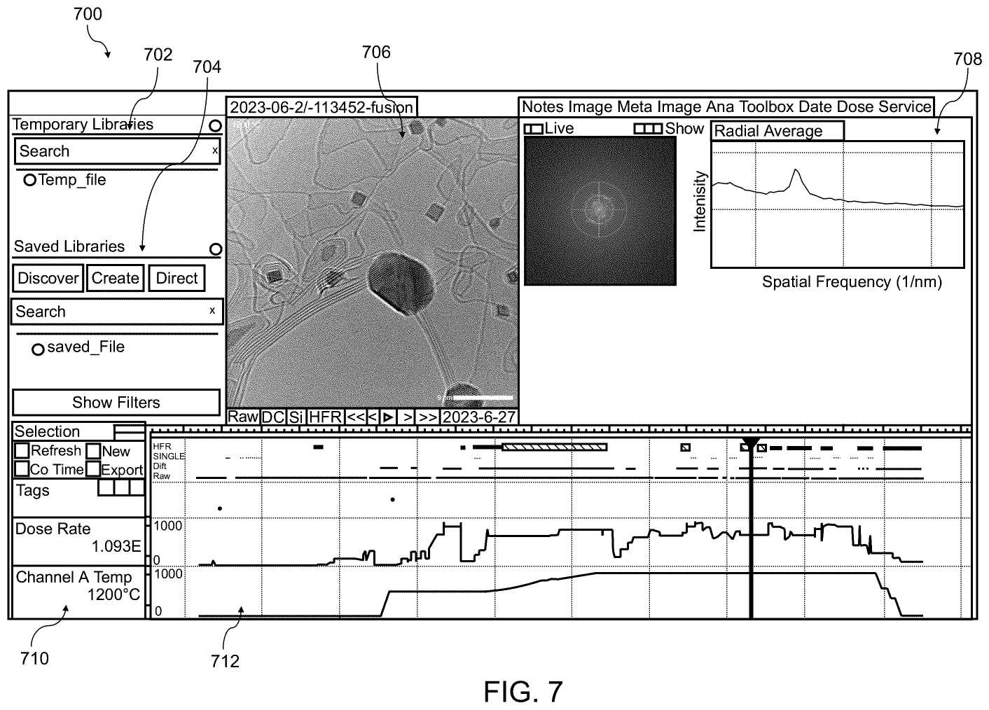

FIG. 7 depicts a view of the UI of the system described herein showing available HFR data and consolidated HFR data. Referring to FIG. 7, UI 700 includes a temporary libraries 702 and a saved libraries 704 for selecting from among one or more temporary or saved libraries or files. A main view 706 shows an image of a biological sample imaged by the TEM. A radial average view 708 depicts a graph of intensity versus spatial frequency. Various filters 710 may be applied for selectively viewing the image data, and a timeline 712 may display both available HFR data that and consolidated HFR data.

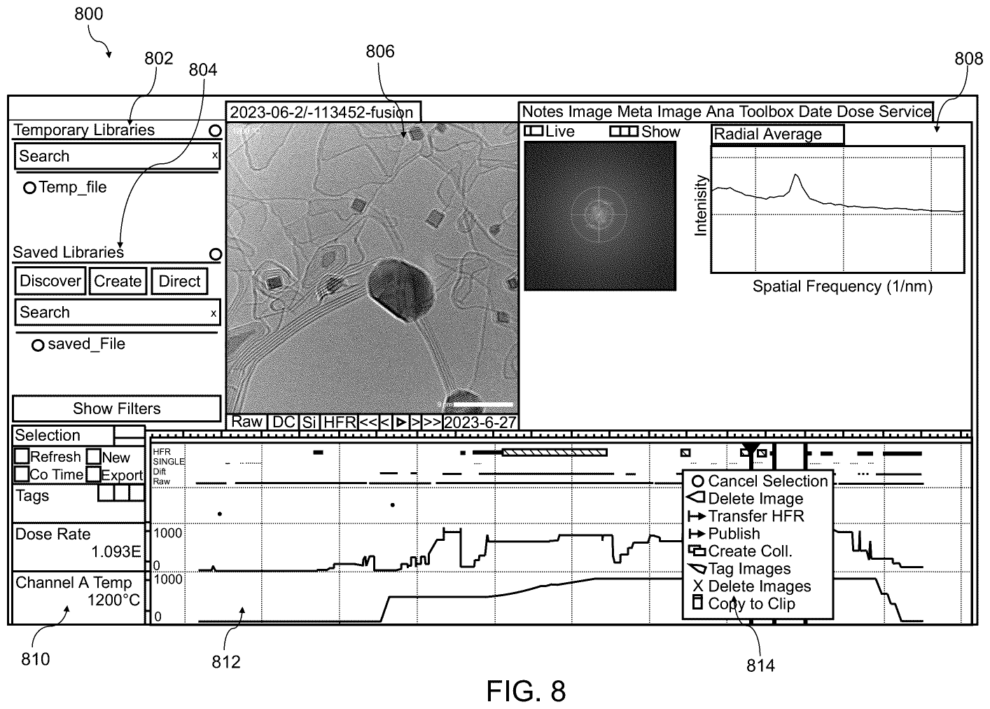

Thus, in the screenshot shown in FIG. 7, there is depicted a first section of the HFR data (e.g., in pink, dashed lines, or other visual identifier) and a second section (e.g., in gray or another visual identifier). The first, pink, section may represent the data already transferred or consolidated into the library. The second, gray, section may represent what is available on the camera computer. Then in FIG. 8, the user highlights a selection of the available gray data and decides to transfer it into this library, adding to the pink available data in the library.

FIG. 8 depicts a detailed view the UI in FIG. 7 showing consolidated HFR data. Like UI 700 in FIG. 7, UI 800 in FIG. 8 includes a temporary libraries 802 and a saved libraries 804 for selecting from among one or more temporary or saved libraries or files. A main view 806 shows an image of a biological sample imaged by the TEM. A radial average view 808 depicts a graph of intensity versus spatial frequency. Various filters 810 may be applied for selectively viewing the image data, and a timeline 812 may display both available HFR data that and consolidated HFR data. A dialog box 814 allows the user to consolidated selected HFR data. Here, user-selectable options may include cancel selection, delete image, transfer HFR, publish, create collection, tag image, and copy to clip.

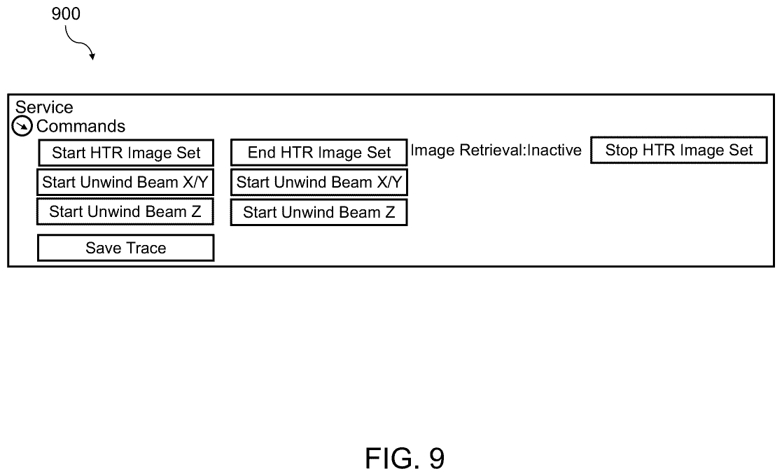

FIG. 9 depicts a high temporal resolution (HTR) UI 900 presented by the data management system described herein. Referring to FIG. 9, the current Synchronicity HTR UI shown may be augmented, as discussed herein, to include an Indicator for Image Retrieval, Progress for Image Retrieval, Record location, and a Start/Stop toggle. It is appreciated that in some embodiments, image retrieval may not continue beyond the session.

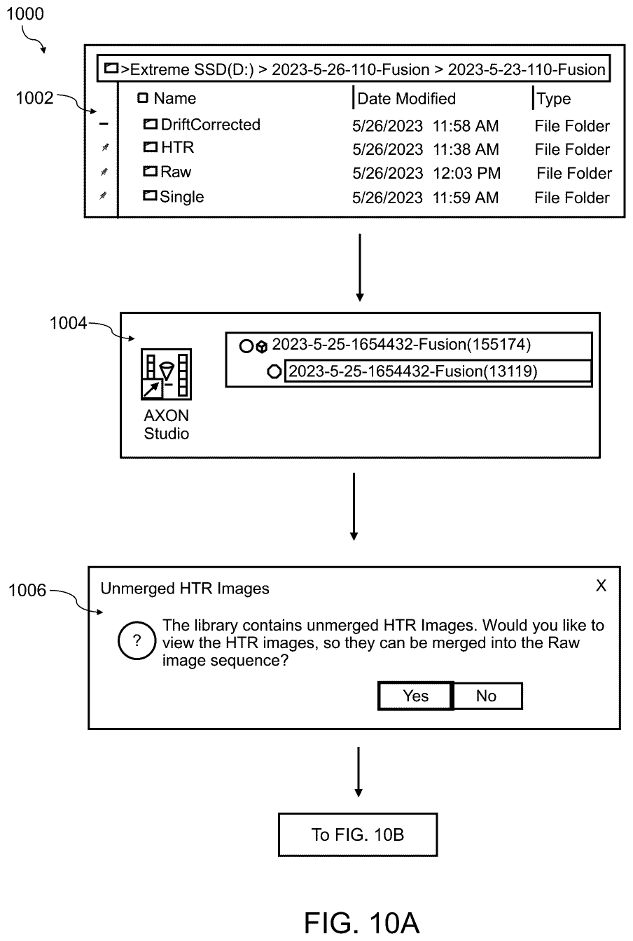

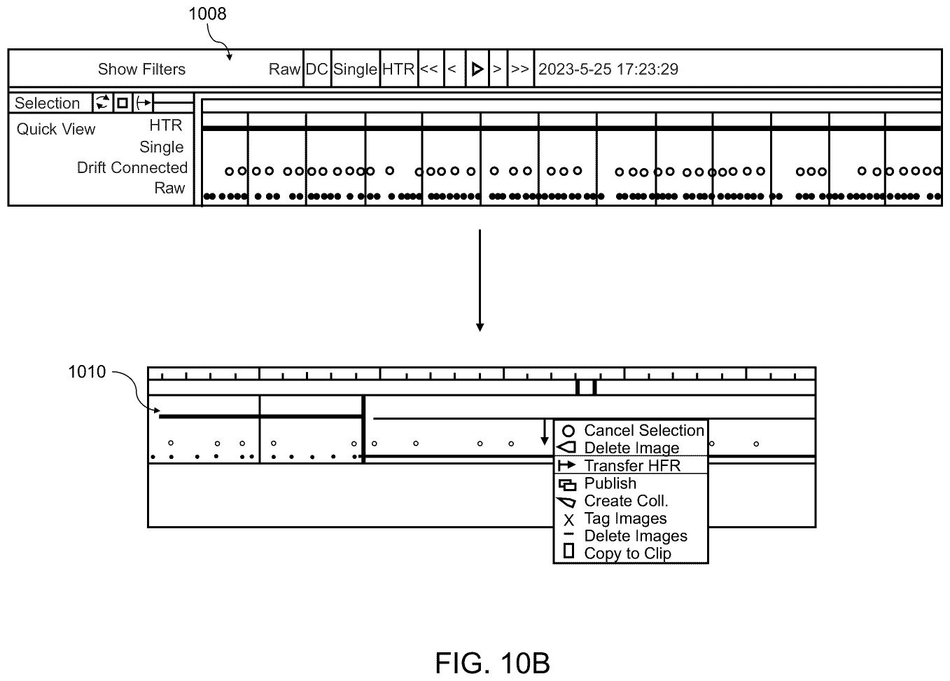

FIG. 10A depicts a first part of a sequence for managing TEM images and metadata according to an embodiment described herein. FIG. 10B depicts a second part of the sequence in FIG. 10A for managing TEM images and metadata according to an embodiment described herein. Referring to FIGS. 10A and 10B, the data management sequence or workflow 1000 progresses through UI screens 1002, 1004, 1006, 1008, and 1010. For example, a first step may be that HTR images are normalized and synchronized with the Raw images in the session. But they are not yet included in .axon.db and aren't yet metadata rich.

Next, opening the session in AXON Studio may prompt the user if they would like to view the HTR images. This uses metadata from nearby Raw images to fill in HTR metadata. Data may be held in memory the timeline may be populated for all Studio features.

At a third step, users can Merge HTR-formatted image data to Raw-formatted image data. A Raw mage file contains unprocessed or minimally processed data from the image sensor of a digital camera or other image sensor. This can include replacing redundant Raw images with the HTR sequences, including image paths/data in the .axon.db database, and facilitating drift corrected collections of these images.

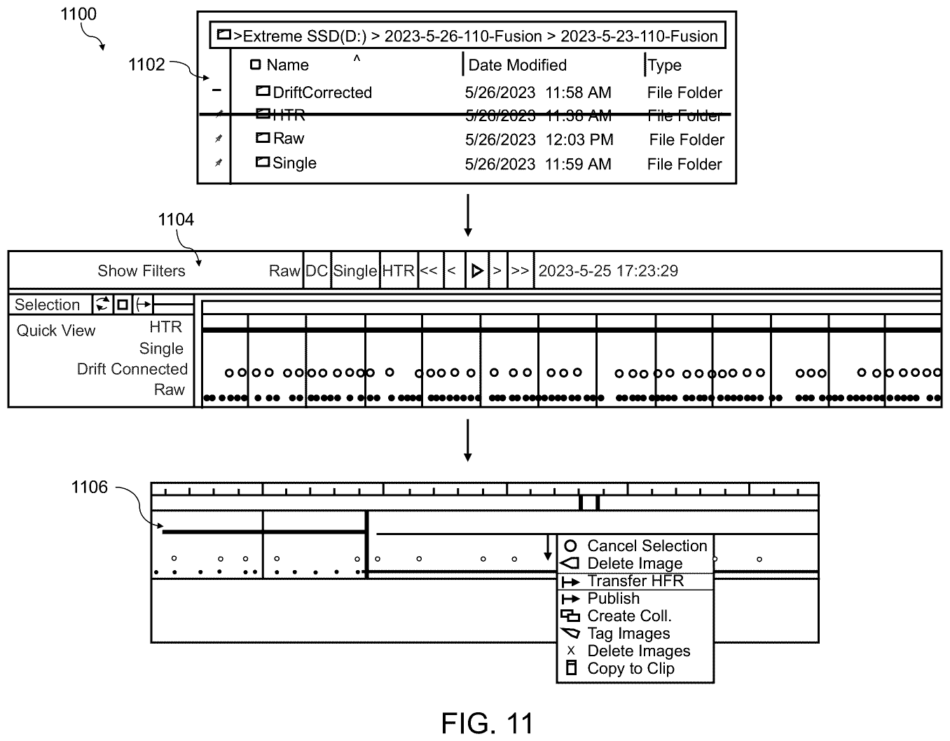

FIG. 11 depicts an alternative data management sequence for managing TEM images and metadata to the sequence shown in FIGS. 10A and 10B.

In this first alternative workflow 1100, which progresses through UI screens 1102, 1104, and 1106, Synchronicity doesn't manage image transfer and a user goes through more time-consuming steps in Studio. Instead, where there are HTR sequences, Synchronicity and AXON Services manage data but do not pull the images over yet and do not normalize them yet. AXON Studio may then manage the following through a Merge function: initiate data transfer to the AXON PC; convert/normalize images if necessary and synchronize metadata; include image paths/data in the .database; and provide workflows to drift correct this data if necessary. This may allow users to be more selective in the HTR data included, avoiding unnecessary bloat in the library. Studio steps could still be initiated during a live session in Synchronicity.

The alternative workflow sequence 1100 may begin by opening the session in AXON Studio, which may include showing the user where HTR images are stored on the imaging PC. It is noted, however, that the user may not be able to view these images because the images would be stored on another computer but the user may view the corresponding Raw/DC images to decide what they want to transfer. Next, users can Merge HTR to Raw to: initiate data transfer to the AXON PC, convert/normalize images and synchronize metadata, include image paths/data in the .axon.db, and facilitate DC collections of this data.

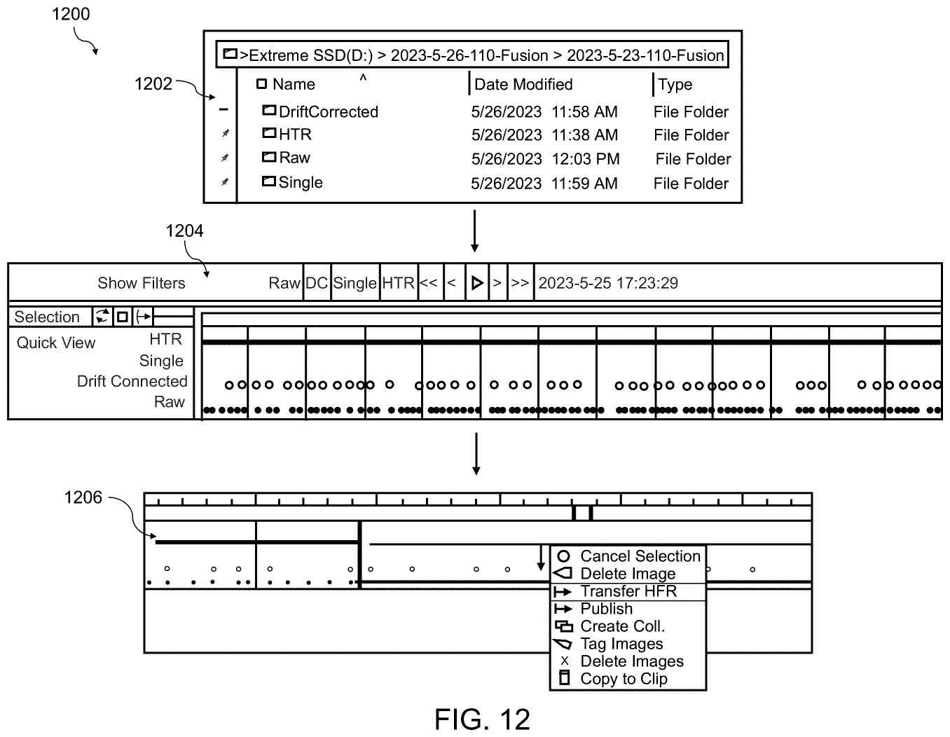

FIG. 12 depicts an alternative data management sequence for managing TEM images and metadata to the sequence shown in FIGS. 10A and 10B. In this second alternative workflow 1200, which progresses through UI screens 1202, 1204, and 1206, Synchronicity does more than image retrieval, but may also be used for assigning metadata and including image data/paths in the database.

For example, Synchronicity and AXON Services may manage: HTR image transfer to the AXON Core, HTR image normalization, matching Raw images, HTR image synchronization with AXON “Raw” images, inclusion of image path/data in .axon.db, and using metadata from nearby Raw images to fill in HTR metadata. AXON Studio manages the following: To replace redundant Raw images with the image sequence with a higher temporal resolution. To facilitate DC collections of this data. While this doesn't alleviate concerns with image transfer times and bloated libraries, there are less steps for the user in Studio.

The alternative workflow sequence 1200 may begin when HTR images are normalized and synchronized with the Raw images in the session. The images are already included in the .axon.db and are already metadata rich. Users can then merge HTR to Raw to replace redundant Raw images with the image sequence with a higher temporal resolution and to facilitate DC collections of these images.

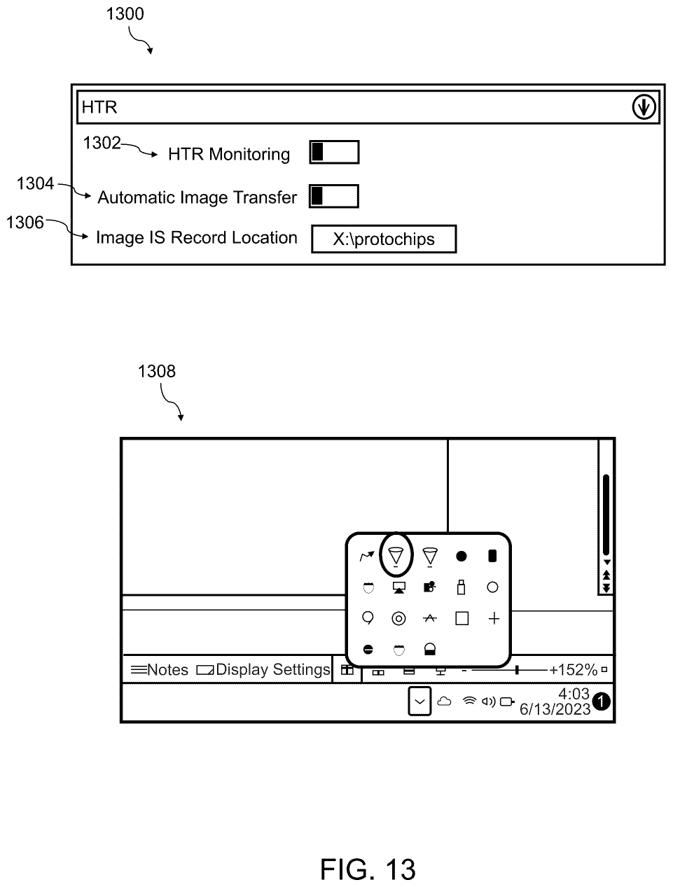

FIG. 13 depicts UI elements for an HTR image transfer service according to one embodiment of the data management system described herein. Referring to FIG. 13, Synchronicity UI 1300 may include HTR monitoring 1302, Automatic Image Transfer 1304, and Image IS Record Location 1306. In a lower portion of the display, which may be provided as a notification tray of an operating system executed on the computing device, an icon 1308 (circled) associated with the HTR Image Transfer Service may be shown.

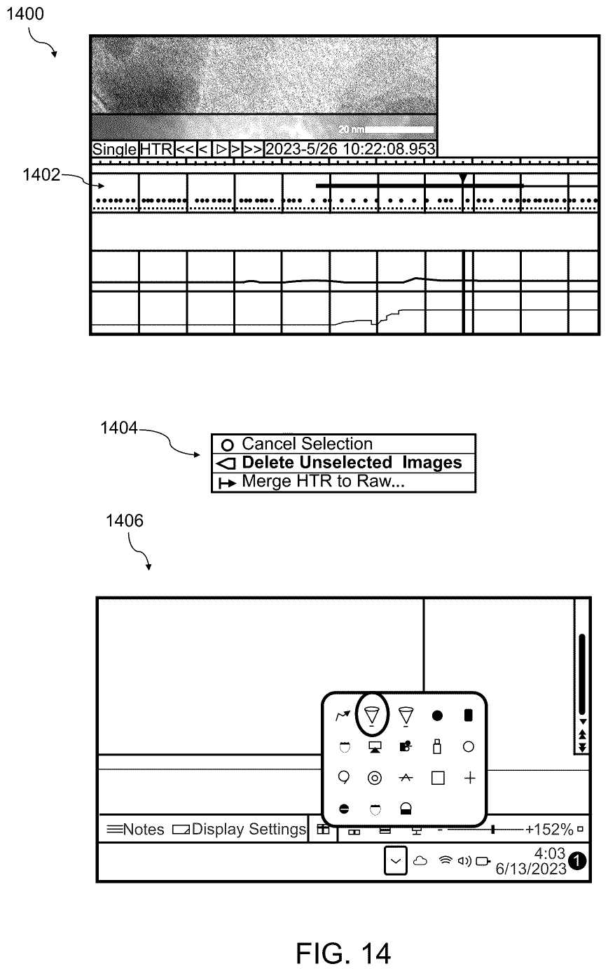

FIG. 14 depicts UI elements 1400 for an HTR image transfer service according to one embodiment of the data management system described herein.

The HTR Image Transfer Service notification tray icon 1308 may change to green when images are transferring, may show progress of images transferring in limited UI. Interacting with the HTR Image Transfer Service notification tray icon 1308, as shown in UI screen 1406, may provide a context menu 1404 to allow the user to select options to Pause/Resume and Stop image transfer and options to Queue Image Transfer for day/time. Right clicking on the context menu available allows the user to select HTR Images that haven't transferred yet and instruct the HTR Image Transfer Service to “Transfer HTR Images”. Additionally, the timeline 1402 may note where there are available HTR Images that have not yet been transferred. The timeline 1402 may also note where there are HTR images that have been transferred.

As will be appreciated by one skilled in the art, aspects of the present disclosure may be embodied as a system, method or computer program product. Accordingly, aspects of the present disclosure may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present disclosure may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium (including, but not limited to, non-transitory computer readable storage media). A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the present disclosure may be written in any combination of one or more programming languages, including an object-oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter situation scenario, the remote computer may be connected to the user's computer through any type of network, including a local area network (LAN) or a wide area network (WAN), or the connection may be made to an external computer (for example, through the Internet using an Internet Service Provider).

Aspects of the present disclosure are described above with reference to flowchart illustrations and/or block diagrams of methods, apparatus (systems) and computer program products according to embodiments of the present disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general-purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The flowchart and block diagrams in the Figures illustrate the architecture, functionality, and operation of possible implementations of systems, methods and computer program products according to various embodiments of the present disclosure. In this regard, each block in the flowchart or block diagrams may represent a module, segment, or portion of code, which comprises one or more executable instructions for implementing the specified logical function(s). It should also be noted, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

The terminology used herein is for the purpose of describing particular embodiments only and is not intended to be limiting of the present disclosure. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the present disclosure in the form disclosed. Many modifications and variations will be apparent to those of ordinary skill in the art without departing from the scope and spirit of the present disclosure. The embodiments were chosen and described in order to best explain the principles of the present disclosure and the practical application, and to enable others of ordinary skill in the art to understand the present disclosure for various embodiments with various modifications as are suited to the particular use contemplated.

These and other changes can be made to the disclosure in light of the Detailed Description. While the above description describes certain embodiments of the disclosure, and describes the best mode contemplated, no matter how detailed the above appears in text, the teachings can be practiced in many ways. Details of the system may vary considerably in its implementation details, while still being encompassed by the subject matter disclosed herein. As noted above, particular terminology used when describing certain features or aspects of the disclosure should not be taken to imply that the terminology is being redefined herein to be restricted to any specific characteristics, features, or aspects of the disclosure with which that terminology is associated. In general, the terms used in the following claims should not be construed to limit the disclosure to the specific embodiments disclosed in the specification, unless the above Detailed Description section explicitly defines such terms. Accordingly, the actual scope of the disclosure encompasses not only the disclosed embodiments, but also all equivalent ways of practicing or implementing the disclosure under the claims.

What is claimed is:

1. A system for selectively managing different temporal and/or spatial resolution images and metadata collected during a transmission electron microscope (TEM) session, the system comprising:
a transmission electron microscope; and
a computer system communicatively coupled to the transmission electron microscope, the computer system comprising:
a memory; a
a data storage; and
at least one processor configured for:
continuously receiving, from the transmission electron microscope, data captured at a lower temporal and/or spatial resolution; and
selectively receiving, from the transmission electron microscope, data captured at a higher temporal and/or spatial resolution.

2. The system of claim 1, wherein the data includes a plurality of images and associated metadata.

3. The system of claim 1, wherein selectively receiving the higher resolution data is performed in response to a trigger.

4. The system of claim 1, wherein selectively receiving the higher resolution data includes communicating with the transmission electron microscope for selectively recording the higher resolution data.

5. The system of claim 4, wherein the selective recording of the higher temporal resolution and/or spatial resolution images is manually triggered by a user interacting with a camera or imaging software.

6. The system of claim 3, wherein the selective recording of the higher temporal resolution and/or spatial resolution images is triggered automatically.

7. The system of claim 6, wherein automatically triggering the recording of the higher temporal resolution and/or spatial resolution images is based on the data captured at a lower temporal resolution and/or lower spatial resolution.

8. The system of claim 2, wherein the processor is further configured for generating a visual representation of the image data and the metadata in an interactive timeline format.

9. The system of claim 8, wherein the processor is further configured for scrubbing the images and plot data to allow a user to interact with the TEM session.

10. The system of claim 8, wherein the processor is further configured for painting a data layer on the interactive timeline, the data layer showing any available higher temporal and/or spatial resolution data.

11. The system of claim 1, wherein the processor is further configured for synchronizing a lower resolution data stream comprising information captured at the lower temporal resolution and/or lower spatial resolution with a higher resolution data stream comprising information captured at the higher temporal resolution and/or higher spatial resolution.

12. The system of claim 11, wherein the data streams are synchronized using a software application or service.

13. The system of claim 12, wherein the software application or service is executed on multiple different computers.

14. The system of claim 12, wherein storage of the data streams is distributed across one or more data storage devices, storage servers, or databases.

15. The system of claim 14, wherein synchronizing the data streams is based on an indication in a first data storage location that higher resolution data is available in a second data storage location.

16. The system of claim 11, wherein synchronizing the data streams includes comparing the lower resolution data stream with the higher resolution data stream as part of an image analysis.

17. The system of claim 16, wherein the image analysis includes determining, based on the lower temporal resolution data stream, whether to transfer a sequence of the higher resolution data stream.

18. The system of claim 16, wherein the image analysis includes determining that a first sequence of the lower resolution data stream and a second sequence of the higher resolution data stream are associated with the same pixel resolution and, in response, merging the first and second sequences into the same data stream.

19. The system of claim 1, wherein the processor is further configured for performing drift correction during the TEM session in real time or near real time.

20. The system of claim 19, wherein performing drift correction includes performing physical drift correction.

21. The system of claim 19, wherein performing drift correction includes performing digital drift correction.

22. The system of claim 19, wherein the data includes a set of drift-corrected images.

23. The system of claim 19, wherein the drift correction performed on the higher resolution images and metadata is based on the lower resolution images and metadata.

24. The system of claim 19, wherein the processor is further configured for saving the higher resolution drift corrected images and metadata in addition to the lower resolution images and metadata.

25. The system of claim 19, wherein the processor is further configured for saving the higher resolution drift corrected images and metadata instead of the lower resolution images and metadata.

26. The system of claim 2, wherein the processor is further configured for applying data management practices to the image data streams.

27. The system of claim 26, wherein the applied data management practice includes one or more of:
saving every Nth image of the continuously captured plurality of images;
digitally summing pixels in a blocked average;
digitally summing in a rolling average;
digitally averaging pixels in a blocked average;
digitally averaging pixels in a rolling average;
binning images from a first pixel resolution to a second pixel resolution; and
selectively receiving the images at their original speed and resolution.

28. A computer system for selectively managing different temporal and/or spatial resolution images and metadata collected during a transmission electron microscope (TEM) session, the computer system comprising:
a memory; a
database; and
at least one processor configured for:
continuously receiving, from the transmission electron microscope, data captured at a lower temporal and/or spatial resolution; and
selectively receiving, from the transmission electron microscope, data captured at a higher temporal and/or spatial resolution.

29. A non-transitory computer-readable storage medium, the non-transitory computer-readable storage medium storing instructions to be implemented on at least one computing device including at least one processor, the instructions when executed by the at least one processor cause the at least one computing device to perform a method for selectively managing different temporal and/or spatial resolution images and metadata collected during a transmission electron microscope (TEM) session, the method comprising:
continuously receiving, from the transmission electron microscope, data captured at a lower temporal and/or spatial resolution; and
selectively receiving, from the transmission electron microscope, data captured at a higher temporal and/or spatial resolution.

30. A method for selectively managing different temporal and/or spatial resolution images and metadata collected during a transmission electron microscope (TEM) session, the method comprising:
by a transmission electron microscope and a computer system communicatively coupled to the transmission electron microscope:
continuously receiving, from the transmission electron microscope, data captured at a lower temporal and/or spatial resolution; and
selectively receiving, from the transmission electron microscope, data captured at a higher temporal and/or spatial resolution.
